(19) United States
(12) Patent Application Publication
(10) Pub. No.: US 2024/0413159 A1
(43) Pub. Date: Dec. 12, 2024

(54) COMPLEMENTARY METAL-OXIDE-SEMICONDUCTOR CIRCUIT

(71) Applicant: Invention and Collaboration Laboratory, Inc., Taipei City (TW)

(72) Inventors: Chao-Chun Lu, Taipei City (TW); Wen-Hsien Tu, Taipei City (TW)

(73) Assignee: Invention and Collaboration Laboratory, Inc., Taipei City (TW)

(21) Appl. No.: 18/736,565

(22) Filed: Jun. 7, 2024

Related U.S. Application Data
(60) Provisional application No. 63/471,982, filed on Jun. 9, 2023.

(51) Int. Cl. H01L 27/092

(52) U.S. Cl. CPC H01L 27/0925; H01L 27/0924

(57) ABSTRACT

A complementary metal-oxide-semiconductor (CMOS) circuit includes a bulk semiconductor substrate, a first active region and a second active region, a first type transistor, a first localized isolating layer, a second type transistor, and a second localized isolating layer. The bulk semiconductor substrate has an original semiconductor surface. The first active region and the second active region are formed based on the bulk semiconductor substrate. The first type transistor is formed based on the first active region and has a first doped body. The first localized isolating layer is under the first type transistor and at least isolates the first doped body from the bulk semiconductor substrate. The second type transistor is formed based on the second active region and has a second doped body. The second localized isolating layer is under the second type transistor and at least partially isolates the second doped body from the bulk semiconductor substrate.

### CROSS REFERENCE TO RELATED APPLICATIONS

This application claims the benefit of U.S. Provisional Application No. 63/471,982, filed on Jun. 9, 2023. The content of the application is incorporated herein by reference.

### BACKGROUND OF THE INVENTION

### 1. Field of the Invention

The present invention relates to a CMOS (complementary metal-oxide-semiconductor) circuit, and particularly to a CMOS circuit which can have lower cost, improve leakage current and latch up issues in the CMOS structure, solve floating body effect in the conventional SOI (Silicon Over Isolator) wafer, no ion-implantation process for doping the Source/Drain regions, and reduce leakage currents.

### 2. Description of the Prior Art

The traditional SOI (Silicon on Insulator) transistor is generally made in an entire SOI wafer which is much more expensive than a Bulk Silicon wafer. As a result one disadvantage of the SOI transistor technology is that the cost per each transistor made in a SOI wafer is much higher than that made in a bulk silicon wafer. The other disadvantage is that the cost for each SOI transistor, therefore, can hardly meet the demand on cost reduction per scaled process node as Moore's Law dictates, so SOI technology did not become a mainstream or a commodity process technology that is dominated by the Bulk-Silicon-substrate technology. Several novel methods are used to prepare the SOI wafer; for example, bonding together two wafers each of which has Silicon oxide on the surface of a bulk-substrate wafer, respectively, and then by flipping one wafer on the other wafer and due to mutual oxide binding forces these two wafers are connected with these two layers of oxide to be sandwiched in between two oxide-covered bulk wafers; afterwards one wafer is ground to a specific thickness to result in a SOI wafer. The other method is implanting oxide atoms through the silicon wafer surface, which results in a thin silicon film over the implanted oxide layer which has been created on the original bulk semiconductor substrate. Both methods are used to create an entire SOI wafer at much higher costs than that of a Bulk Silicon wafer, especially to the larger wafer diameter (e.g. 8 inches or 12 inches). Then the well-known silicon processing method can create the MOSFET (Metal-Oxide-Semiconductor Field-Effect-Transistor) in a SOI wafer.

Although the SOI transistor is more costly made, there are several advantages for using SOI transistors to create integrated circuits: (1) Each transistor is fully isolated from the other transistor; (2) The parasitic capacitances associated with Source and Drain regions of an MOSFET (Metal-Oxide-Semiconductor Field-Effect Transistors) are significantly reduced; (3) If a CMOS (Complementary Metal-Oxide-Semiconductor) configuration is needed, there is no latch-up concern between NMOS (n-type Metal-Oxide-Semiconductor) and PMOS (p-type Metal-Oxide-Semiconductor) transistors, which thus significantly reduces the planar area in contrast to that of a Bulk-substrate CMOS technology; (4) As a FinFET or Tri-Gate technology is used in a fully-depleted SOI transistor, there is no substrate leakage concern.

On the other hand, MOS (Metal-Oxide-Semiconductor) transistor circuit, such as Complementary Metal-Oxide-Semiconductor Field-Effect Transistors (CMOSFET), is widely employed in semiconductor industry. FIG. 1 shows a cross-section view of a state-of-the-art CMOSFET which is most widely used in today's Integrated Circuits (IC). The CMOSFET includes an NMOS (n-type Metal-Oxide-Semiconductor) transistor and a PMOS (p-type Metal-Oxide-Semiconductor) transistor, wherein a Shallow Trench Isolation (STI) region is positioned between the NMOS transistor and the PMOS transistor. The gate structure of the NMOS transistor or the PMOS transistor using some conductive material (like metal, polysilicon or polyside, etc.) over an insulator (such as oxide, oxide/nitride or some high-k dielectric, etc.) is formed on a top of either a planar (planar CMOS) or a 3D silicon surface (such as, Tri-gate or FinFET or Gate-All-Around “GAA” CMOS) whose sidewalls are isolated from those of other transistors by using insulation materials (e.g. oxide or oxide/nitride or other dielectrics). For the NMOS transistor, there are source and drain regions which are formed by an ion-implantation plus thermal annealing technique to implant n-type dopants into a p-type substrate (or a p-well) which thus results in two separated n+/p junction areas. For the PMOS transistor, both source and drain regions are formed by ion-implanting p-type dopants into an n-well which thus results in two p+/n junction areas. Furthermore, to lessen impact ionization and hot carrier injection prior to highly doped n+/p or p+/n junction, it is common to form a lightly doped-drain (LDD) region under the gate structure. Since the NMOS transistor and the PMOS transistor are located respectively inside some adjacent regions of p-substrate and n-well which have been formed next to each other within a close neighborhood, a parasitic junction structure called n+/p/n/p+ (the path marked by dash line in FIG. 1 is called as n+/p/n/p+ Latch-up path) parasitic bipolar device is formed with its contour starting from the n+ region of the NMOS transistor to the p-well to the neighboring n-well and further up to the p+ region of the PMOS transistor.

Once there are significant noises occurred on either n+/p junctions or p+/n junctions, an extraordinarily large current may flow through this n+/p/n/p+ junction abnormally which can possibly shut down some operations of CMOS circuits and to cause malfunction of the entire chip. Such an abnormal phenomenon called Latch-up is detrimental for CMOS operations and must be avoided. One way to increase the immunity to Latch-up which is certainly a weakness for CMOS is to increase the distance from n+ region to the p+ region (labeled as Latch-up Distance in FIG. 1) and both n+ and p+ regions must be designed to be isolated by some vertically oriented oxide (or other suitable insulator materials) as isolation regions which is usually the STI (Shallow Trench Isolation) region. More serious efforts to avoid Latch-up must design a guard-band structure which further increases the distance between n+ regions and p+ regions and/or must add extra n+ regions or p+ regions to collect abnormal charges from noise sources. These isolation schemes always increase extra planar areas to sacrifice the die size of CMOS circuits.

The present invention is to realize a Single-Crystalline Silicon Island On Insulator (SC-SIOI) inside which SOI transistors can be made with no need to use an entire SOI wafer (commonly adopted by the state-of-the art SOI substrate), which thus eliminated the major cost disadvantage due to using the expensive SOI wafer, but keep all advantages of using SOI technology for high performance circuits, especially important for creating higher frequency operation ranges, diminishing noises, reducing power consumption and achieving smaller circuit area especially in a CMOS circuits. With the present invention the SOI transistor is created in a Bulk Silicon (or semiconductor) substrate, i.e. SC-SIOI by using a SOI Island Technology (SOI) without using an entire SOI wafer. Either a transistor or multiple devices are constructed within this SC-SIOI and these devices can be well connected with conductive (such as metal layers) interconnections, thus with less noise disturbances, lower power dissipation and better energy efficiency than those made in the current bulk-substrate transistor/device technology as well as lower cost than those made in the Current SOI technology that uses an entire SOI wafer. For CMOS configuration created in separate SC-SIOI islands there is no need to create extra spaces to avoid latch-up possibility in a commonly-used Bulk CMOS technology.

### SUMMARY OF THE INVENTION

An embodiment of the present invention provides a CMOS (complementary metal-oxide-semiconductor) circuit. The CMOS circuit includes a bulk semiconductor substrate, a first active region and a second active region, a first type transistor, a first localized isolating layer, a second type transistor, and a second localized isolating layer. The bulk semiconductor substrate has an original semiconductor surface. The first active region and the second active region are formed based on the bulk semiconductor substrate. The first type transistor is formed based on the first active region and has a first doped body. The first localized isolating layer is under the first type transistor and at least isolates the first doped body from the bulk semiconductor substrate. The second type transistor is formed based on the second active region and has a second doped body. The second localized isolating layer is under the second type transistor and at least partially isolates the second doped body from the bulk semiconductor substrate.

According to one aspect of the present invention, the CMOS circuit further includes a first shallow trench isolation region and a second shallow trench isolation region, wherein the first shallow trench isolation region surrounds the first active region and the first localized isolating layer, and the second shallow trench isolation region surrounds the second active region and the second localized isolating layer.

According to one aspect of the present invention, the first localized isolating layer fully isolates the first type transistor from the bulk semiconductor substrate, and the second localized isolating layer only partially isolates the second type transistor from the bulk semiconductor substrate, wherein the first type transistor is a PMOS (p-type metal-oxide-semiconductor) transistor and the second type transistor is an NMOS (n-type metal-oxide-semiconductor) transistor.

According to one aspect of the present invention, the second localized isolating layer has an opening from which the second doped body of the NMOS transistor is electrically coupled to the bulk semiconductor substrate.

According to one aspect of the present invention, a length of the opening is around 2˜4 nm.

According to one aspect of the present invention, the opening is a star shape or a non-regular shape.

According to one aspect of the present invention, the first localized isolating layer only partially isolates the first type transistor from the bulk semiconductor substrate, and the second localized isolating layer fully isolates the second type transistor from the bulk semiconductor substrate, wherein the first type transistor is a PMOS transistor and the second type transistor is an NMOS transistor.

According to one aspect of the present invention, the first localized isolating layer has an opening from which the first doped type body of the PMOS transistor body is electrically coupled to the bulk semiconductor substrate.

According to one aspect of the present invention, the first localized isolating layer fully isolates the first type transistor from the bulk semiconductor substrate, and the second localized isolating layer fully isolates the second type transistor from the bulk semiconductor substrate, wherein the first type transistor is a PMOS transistor and the second type transistor is an NMOS transistor.

According to one aspect of the present invention, a source region of the first type transistor abuts against the first localized isolating layer.

According to one aspect of the present invention, the CMOS circuit further includes a metal region contacting a top surface and a sidewall of the source region.

According to one aspect of the present invention, a channel length of the first type transistor is the same or substantially a channel length of the second type transistor.

Another embodiment of the present invention provides a CMOS circuit. The CMOS circuit includes a bulk semiconductor substrate, a first active region and a second active region, a PMOS transistor, a first localized isolating layer, a first shallow trench isolation region, an NMOS transistor, a second localized isolating layer, and a second shallow trench isolation region. The bulk semiconductor substrate has an original semiconductor surface. The bulk semiconductor substrate has an original semiconductor surface. The first active region and the second active region are formed based on the bulk semiconductor substrate. The PMOS transistor is formed based on the first active region and has a first doped body and a first channel. The first localized isolating layer is under the PMOS transistor and at least isolates the first doped body from the bulk semiconductor substrate. The first shallow trench isolation region surrounds the first active region and the first localized isolating layer. The NMOS transistor is formed based on the second active region and has a second doped body and a second channel. The second localized isolating layer is under the NMOS transistor and at least partially isolates the second doped body from the bulk semiconductor substrate. The second shallow trench isolation region surrounds the second active region and the second localized isolating layer. A length of the first channel is the same or substantially the same as a length of the second channel.

According to one aspect of the present invention, the second localized isolating layer has an opening from which the second doped body of the NMOS transistor is electrically coupled to the bulk semiconductor substrate, and a shape of the opening is a star shape or irregular shape.

According to one aspect of the present invention, a length of the opening is between 2˜4 nm.

According to one aspect of the present invention, the opening is a star shape or a non-regular shape.

According to one aspect of the present invention, a source or drain region of the first type transistor abuts against the first localized isolating layer.

According to one aspect of the present invention, the CMOS circuit further includes a metal region contacting a top surface and a sidewall of the drain region.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a state-of-the-art CMOS which includes a p-type metal-oxide-semiconductor (PMOS) transistor and an n-type metal-oxide-semiconductor (NMOS) transistor.

FIG. 2A is a flowchart illustrating an Oxide-PMOS Complementary Metal-Oxide-Semiconductor Field-Effect Transistor (OP-CMOSFET) structure based on a bulk semiconductor substrate according to one embodiment of the present invention.

FIG. 2B, FIG. 2C, FIG. 2D, FIG. 2E are diagrams illustrating FIG. 2A.

FIG. 3 is a diagram illustrating defining an active region of the OP-CMOSFET based on a semiconductor substrate.

FIG. 4, FIG. 5, FIG. 6, FIG. 7, FIG. 8, FIG. 9, FIG. 10, FIG. 11, FIG. 12, FIG. 13, FIG. 14 are diagrams illustrating forming underground insulating layer under the active region of the OP-CMOSFET.

FIG. 15, FIG. 16, FIG. 17, FIG. 18 are diagrams illustrating forming a source region and a drain region in the active region of the OP-CMOSFET.

FIG. 19 is a diagram illustrating forming a gate region above the active region of the OP-CMOSFET.

FIG. 20, FIG. 22, FIG. 23, FIG. 24 are diagrams illustrating various underground insulating layers under the active region of the OP-CMOSFET.

FIG. 21 is a table illustrating the TCAD simulation result of the NMOS transistor which is applied with the Damascene dummy gate/spacer processes

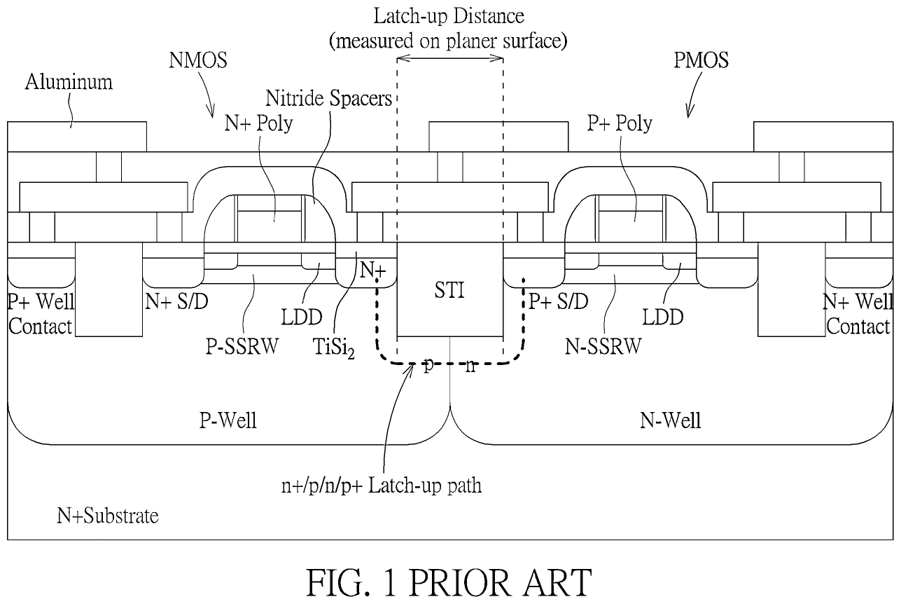

### DETAILED DESCRIPTION

The present invention discloses a novel Oxide-PMOS Metal-Oxide-Semiconductor Field-Effect Transistor (OP-CMOSFET) structure based on a bulk semiconductor substrate, rather than a SOI structure, with localized isolating layers formed under the (p-type Metal-Oxide-Semiconductor) PMOS and NMOS (n-type Metal-Oxide-Semiconductor), respectively. Wherein, the localized isolating layer under the PMOS fully isolates the PMOS transistor body from the bulk semiconductor substrate, but the localized isolating layer under the NMOS transistor body may not fully isolate the NMOS body from the bulk semiconductor and leave an opening from which the electrons accumulated in the NMOS body could leak into the bulk semiconductor substrate to improve the floating body effect. Thus, the present invention greatly improves or even solved most of the problems as stated above in terms of further enhancing CMOS designs during both device and circuit scaling, especially minimizing current leakages, increasing channel-conduction performance and control, increasing higher immunity of CMOS circuits against Latch-up and minimizing the floating body effect.

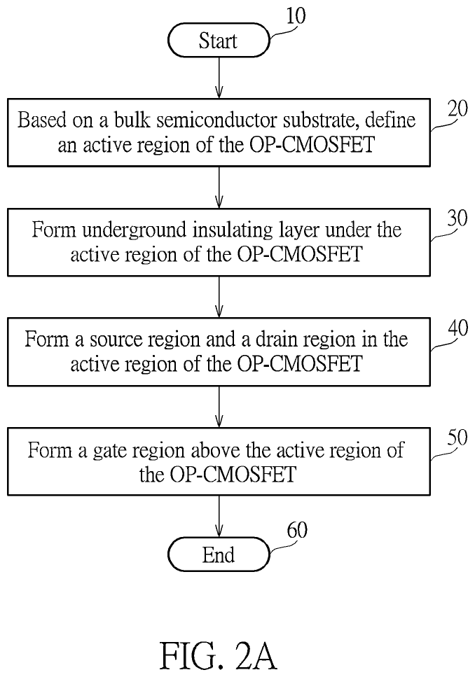

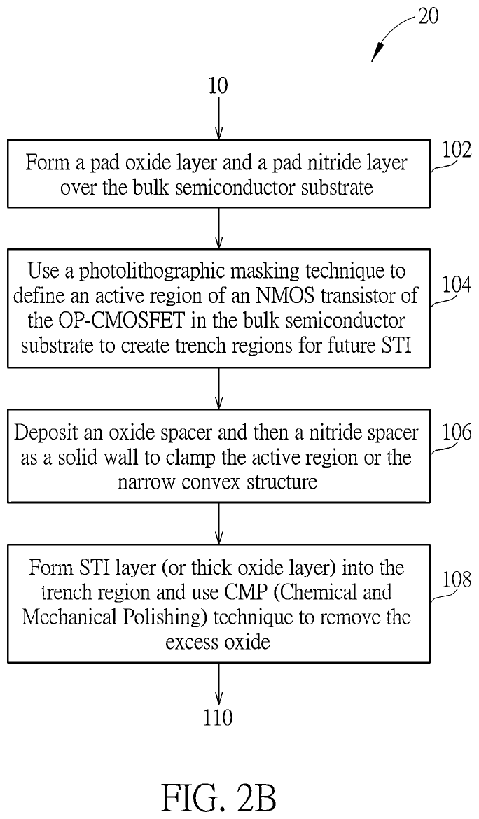

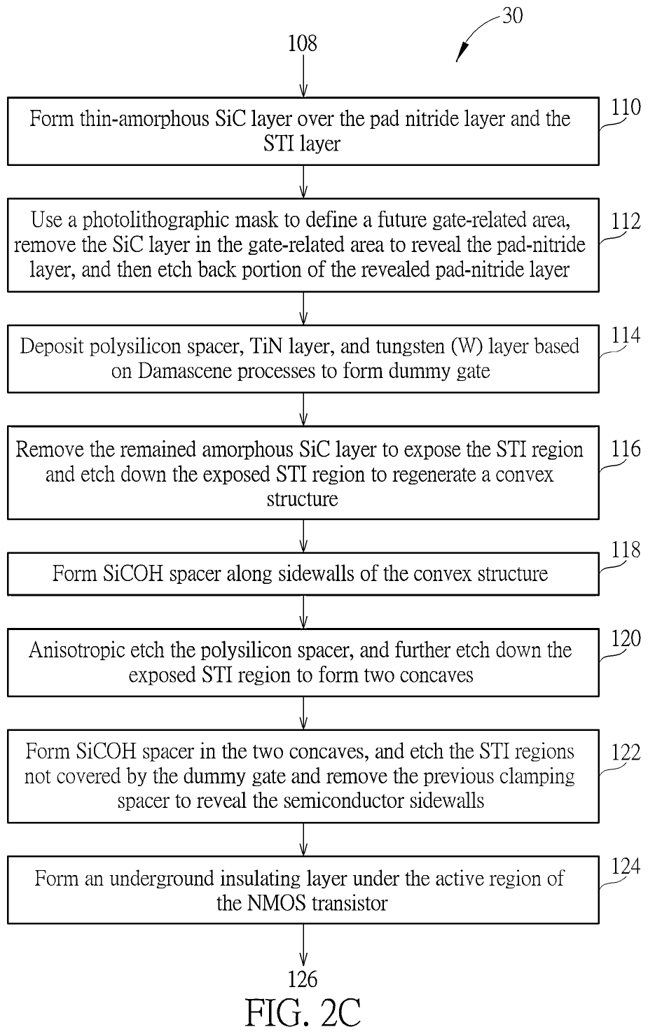

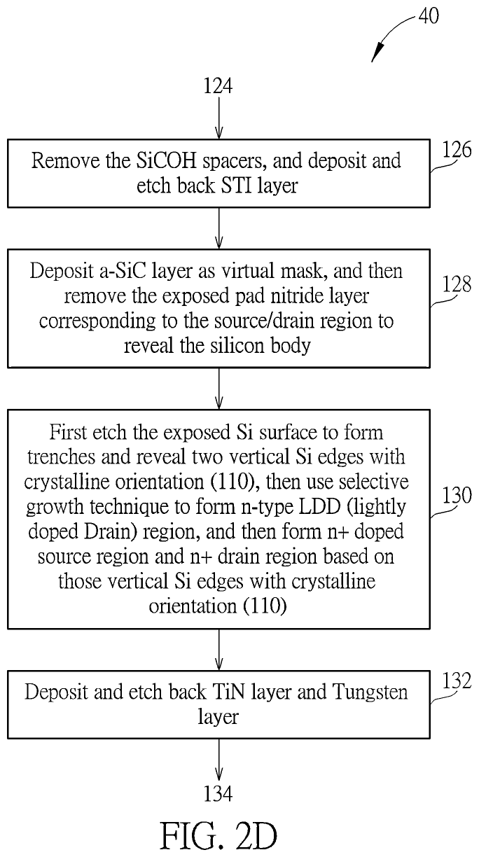

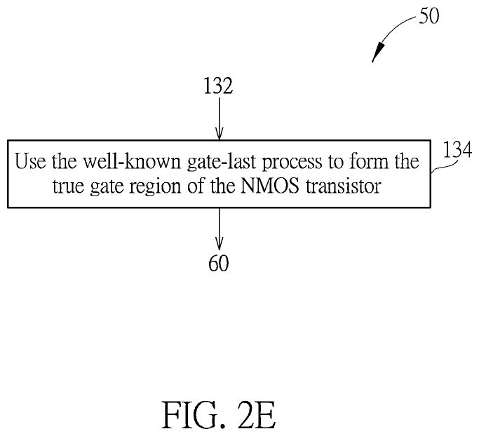

Next, the OP-CMOSFET can be achieved by a manufacture method described in FIG. 2A. Detailed Steps are as follows:
Step 10: Start.
Step 20: Based on a bulk semiconductor substrate, define an active region of the OP-CMOSFET.
Step 30: Form underground insulating layer under the active region of the OP-CMOSFET.
Step 40: Form a source region and a drain region in the active region of the OP-CMOSFET.
Step 50: Form a gate region above the active region of the OP-CMOSFET.
Step 60: End.

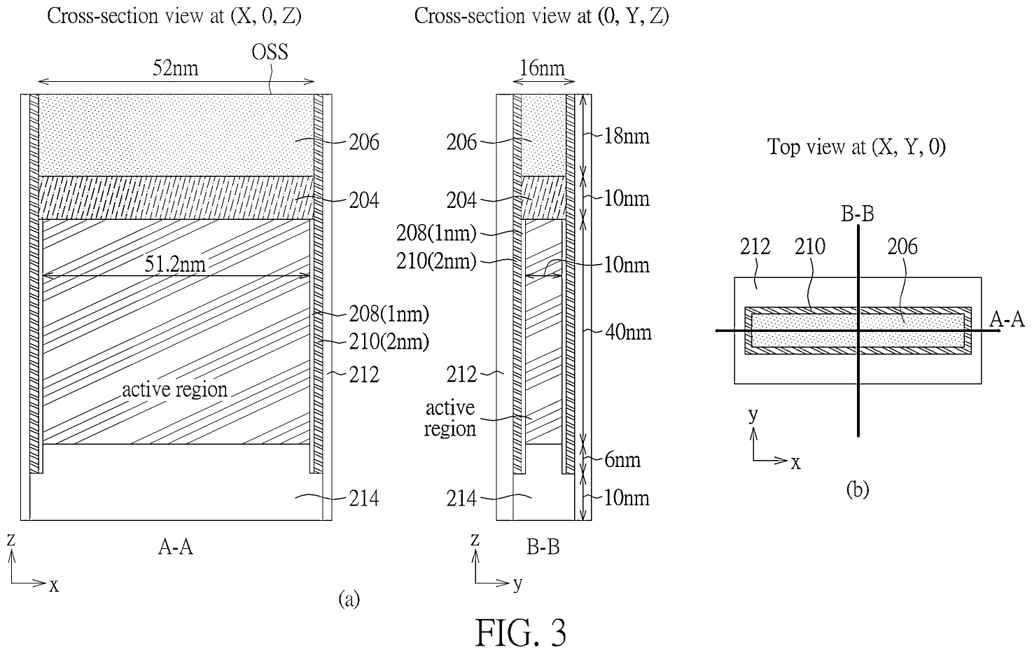

Please refer to FIG. 2B, FIG. 3. Step 20 could include:
Step 102: Form a pad oxide layer 204 and a pad nitride layer 206 over the bulk semiconductor substrate (FIG. 3).
Step 104: Use a photolithographic masking technique to define an active region of an NMOS transistor of the OP-CMOSFET in the bulk semiconductor substrate to create trench regions (e.g. about 300 nm deep) for future STI (FIG. 3).
Step 106: Deposit an oxide spacer (˜1 nm) 208 and then a nitride spacer (˜2 nm) 210 as a solid wall to clamp the active region or the narrow convex structure (FIG. 3).
Step 108: Form STI layer 212 (or thick oxide layer) into the trench region and use CMP (Chemical and Mechanical Polishing) technique to remove the excess oxide (FIG. 3).

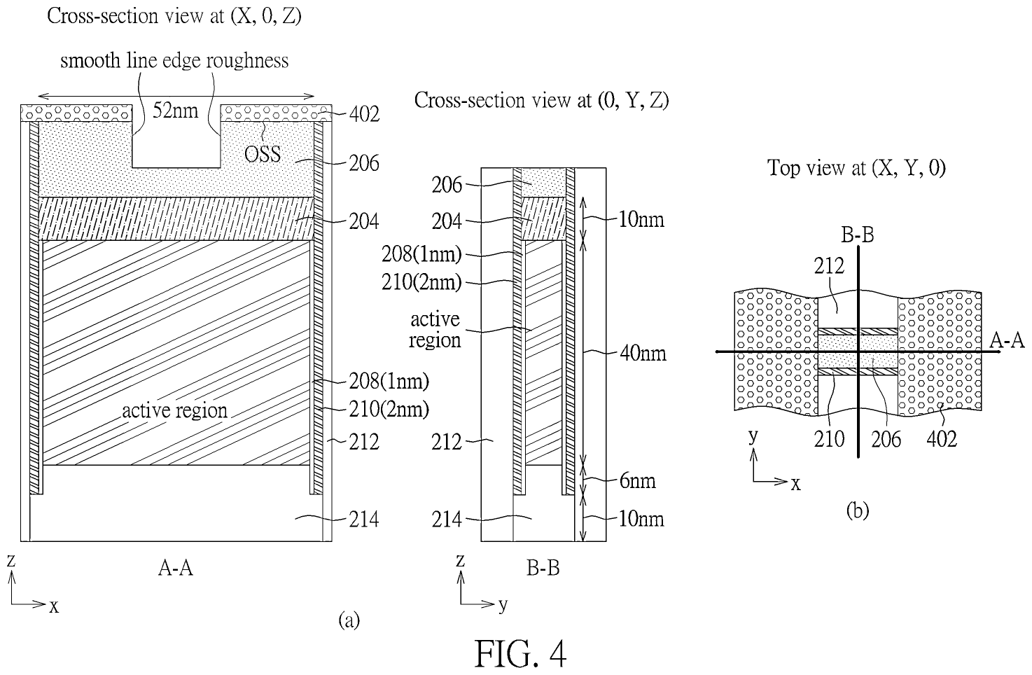

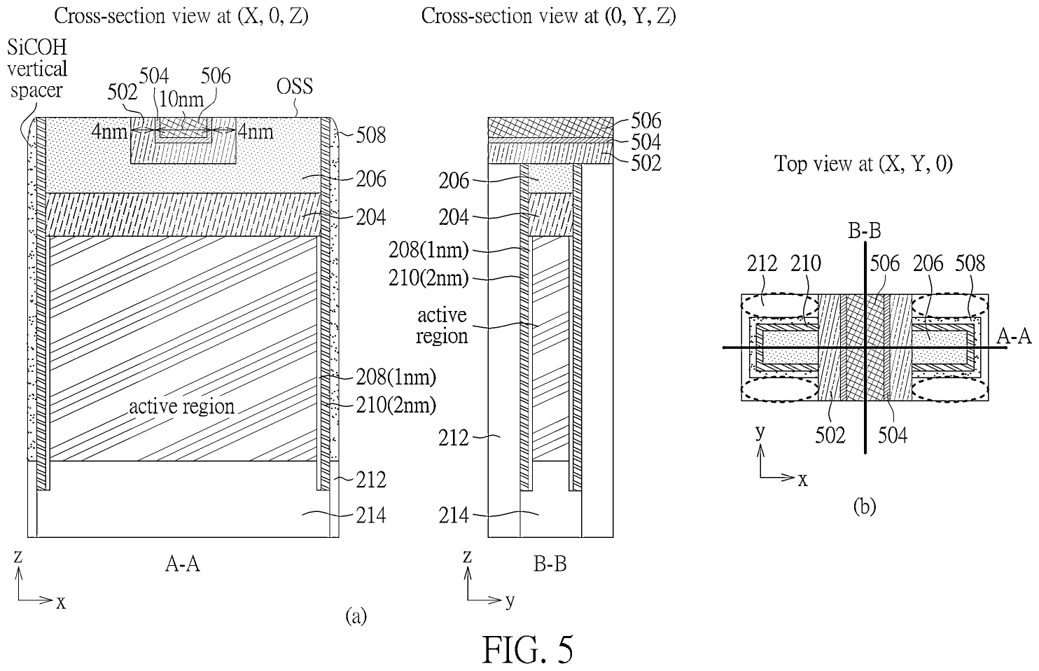

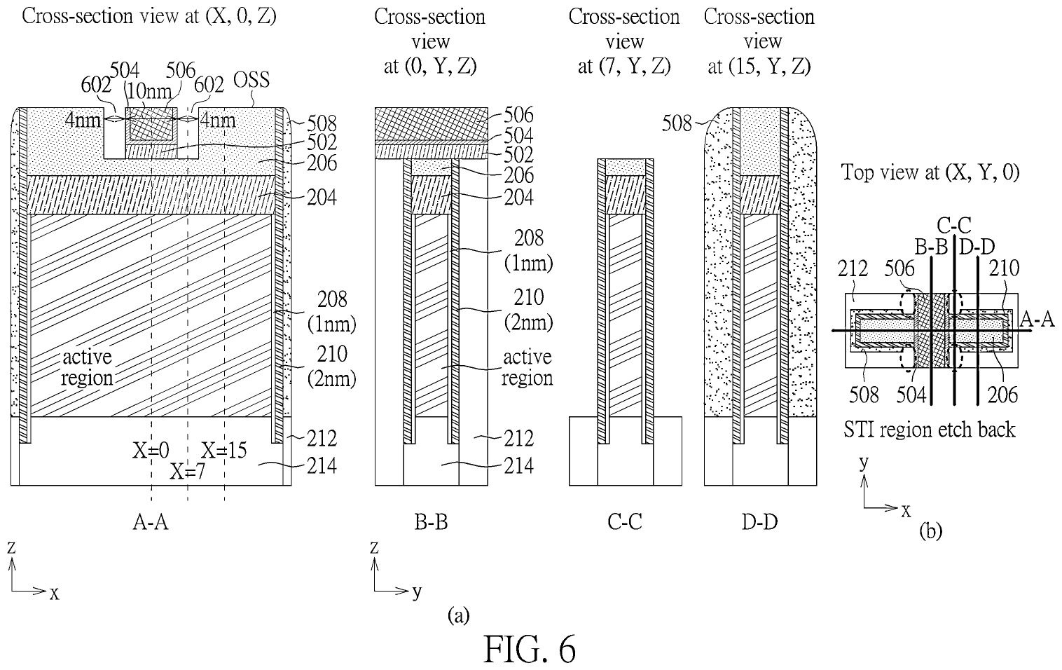

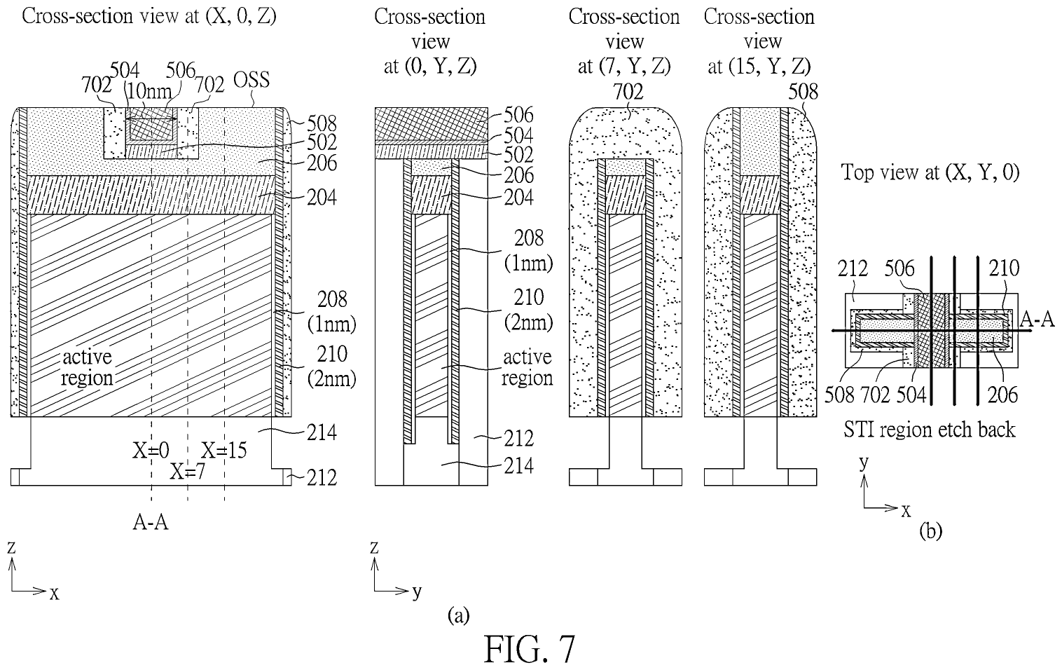

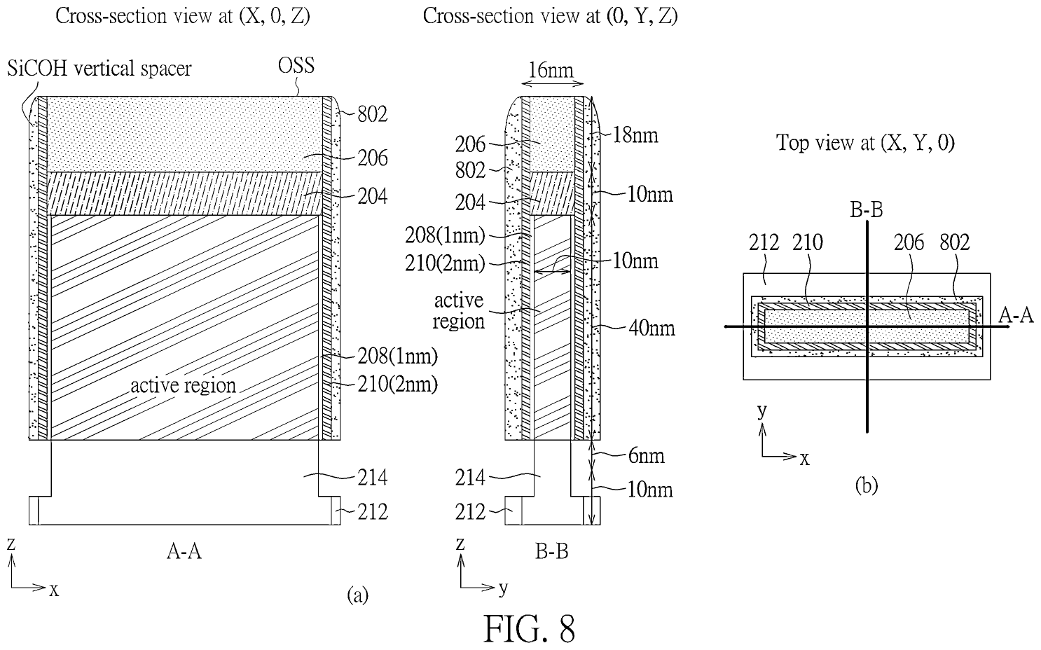

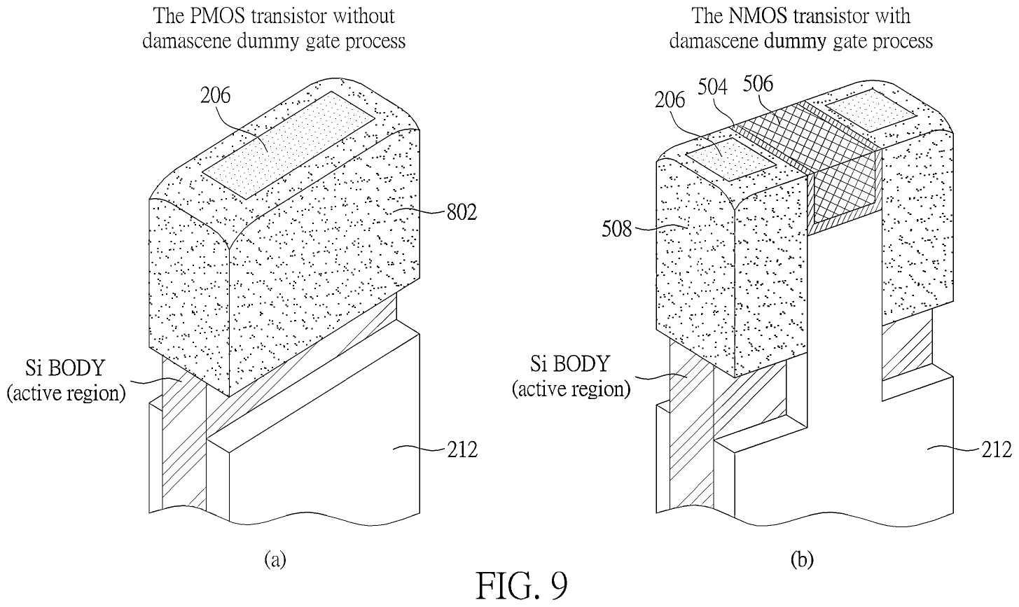

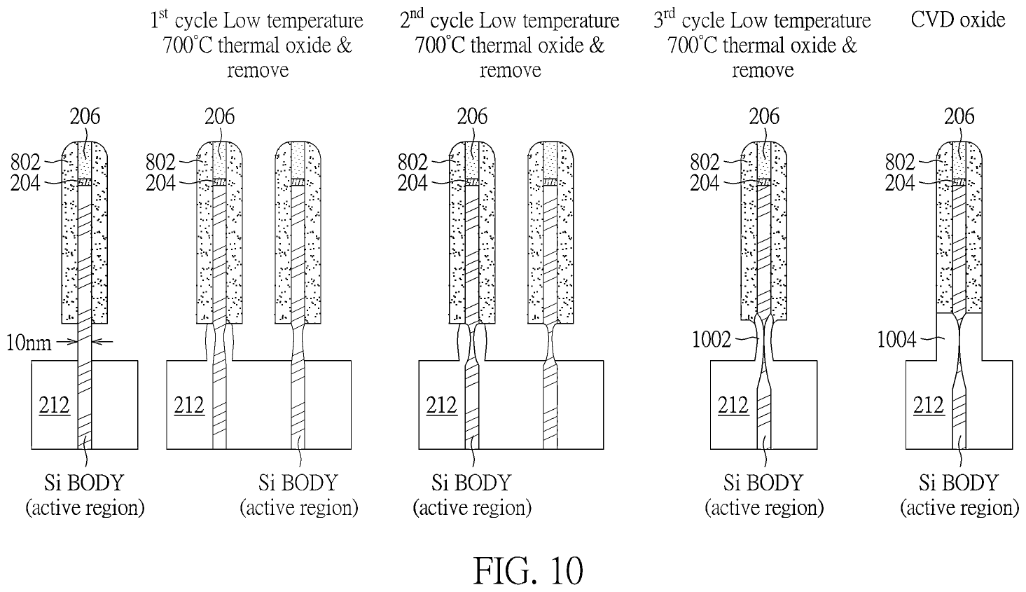

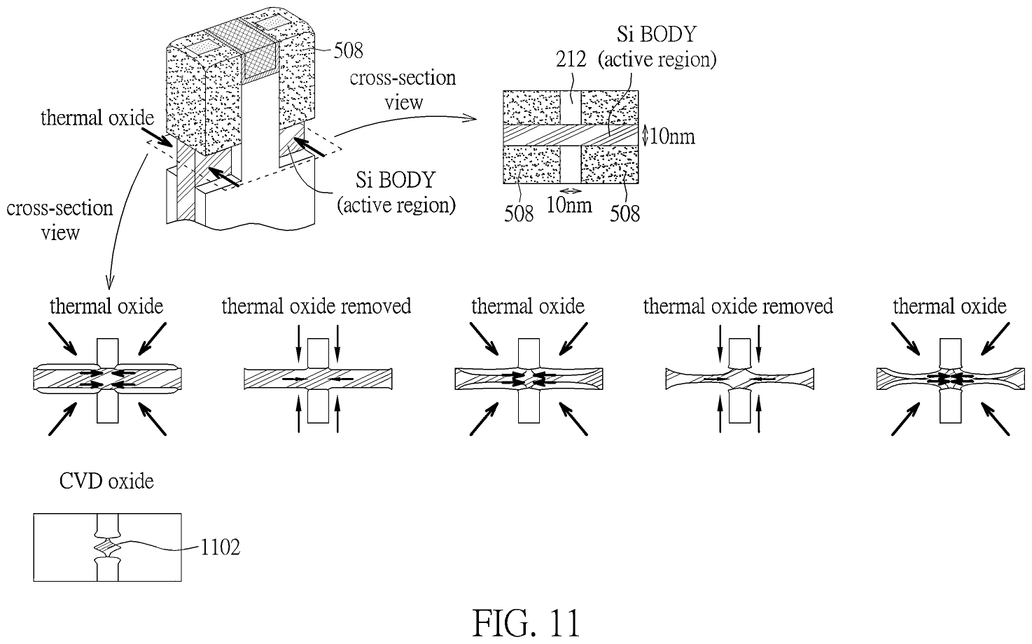

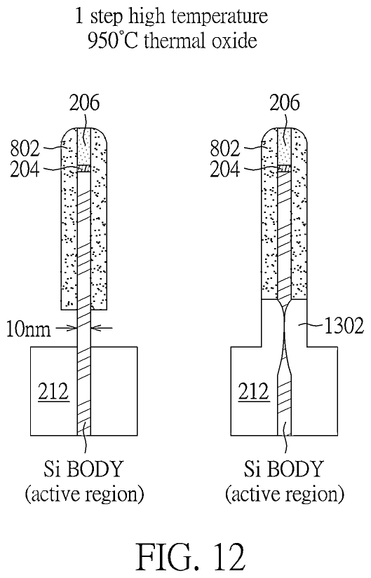

Then, please refer to FIG. 2C, FIG. 4, FIG. 5, FIG. 6, FIG. 7, FIG. 8, FIG. 9, FIG. 10, FIG. 11, FIG. 12, FIG. 13, FIG. 14. Step 30 could include:
Step 110: Form thin-amorphous SiC layer 402 over the pad nitride layer 206 and the STI layer 212 (FIG. 4).
Step 112: Use a photolithographic mask to define a future gate-related area, remove the SiC layer 402 in the gate-related area to reveal the pad-nitride layer 206, and then etch back portion of the revealed pad-nitride layer 206 (FIG. 4).
Step 114: Deposit polysilicon spacer 502, TiN layer 504, and tungsten (W) layer 506 based on Damascene processes to form dummy gate (FIG. 5).
Step 116: Remove the remained amorphous SiC layer 402 to expose the STI region 212 and etch down the exposed STI region 212 to regenerate a convex structure (FIG. 5).
Step 118: Form SiCOH spacer 508 along sidewalls of the convex structure (FIG. 5).
Step 120: Anisotropic etch the polysilicon spacer 502, and further etch down the exposed STI region to form two concaves 602 (FIG. 6).
Step 122: Form SiCOH spacer 702 in the two concaves 602, and etch the STI regions 212 not covered by the dummy gate and remove the previous clamping spacer (the nitride spacer 210 (Si₃N₄)/the oxide spacer 208=2/1 nm) to reveal the semiconductor sidewalls (FIG. 7).
Step 124: Form an underground insulating layer under the active region of the NMOS transistor (FIG. 11).

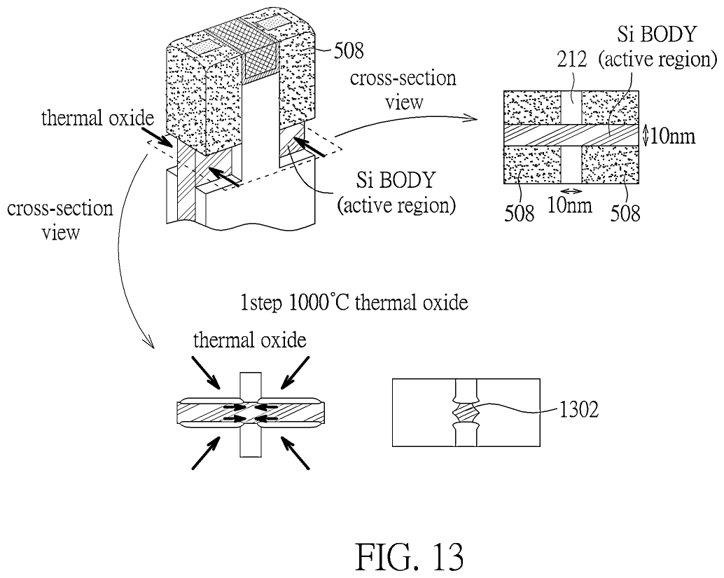

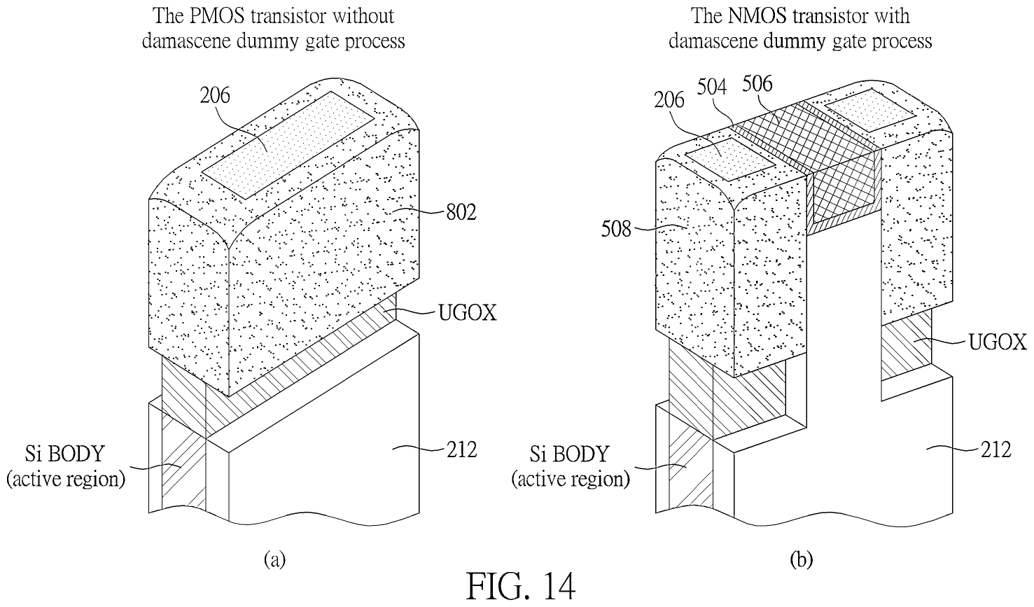

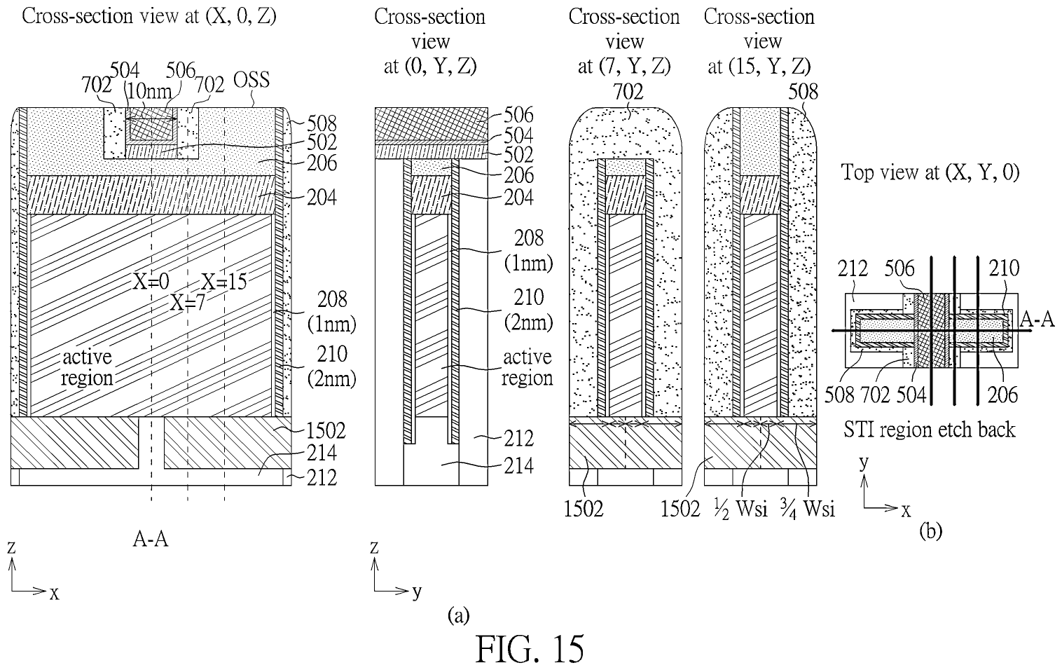

Then, please refer to FIG. 2D, FIG. 15, FIG. 16, FIG. 17, FIG. 18. Step 40 to form exemplary source region and drain region of the NMOS transistor could include:
Step 126: Remove the SiCOH spacers 508, 702, and deposit and etch back STI layer 1602 (FIG. 16).
Step 128: Deposit a-SiC layer 1702 as virtual mask, and then remove the exposed pad nitride layer 206 corresponding to the source/drain region to reveal the silicon body (FIG. 17).
Step 130: First etch the exposed Si surface to form trenches and reveal two vertical Si edges with crystalline orientation (110), then use selective growth technique to form n-type LDD (lightly doped Drain) region 1802, and then form n+ doped source region 1804 and n+ drain region 1806 based on those vertical Si edges with crystalline orientation (110) (FIG. 18).
Step 132: Deposit and etch back TiN layer 1808 and Tungsten layer 1810 (FIG. 18).

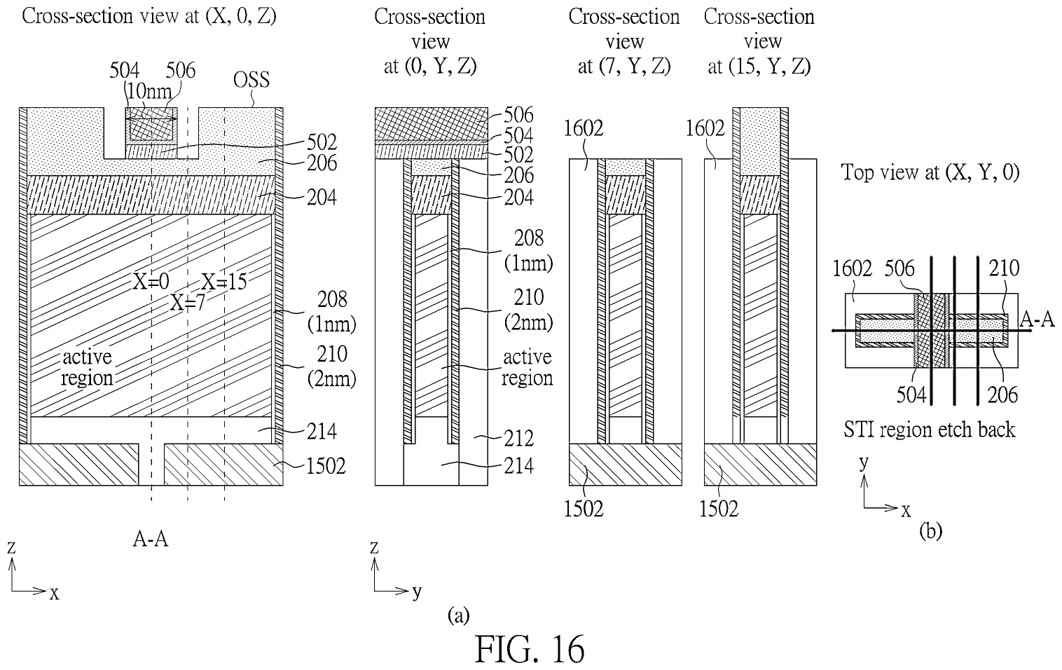

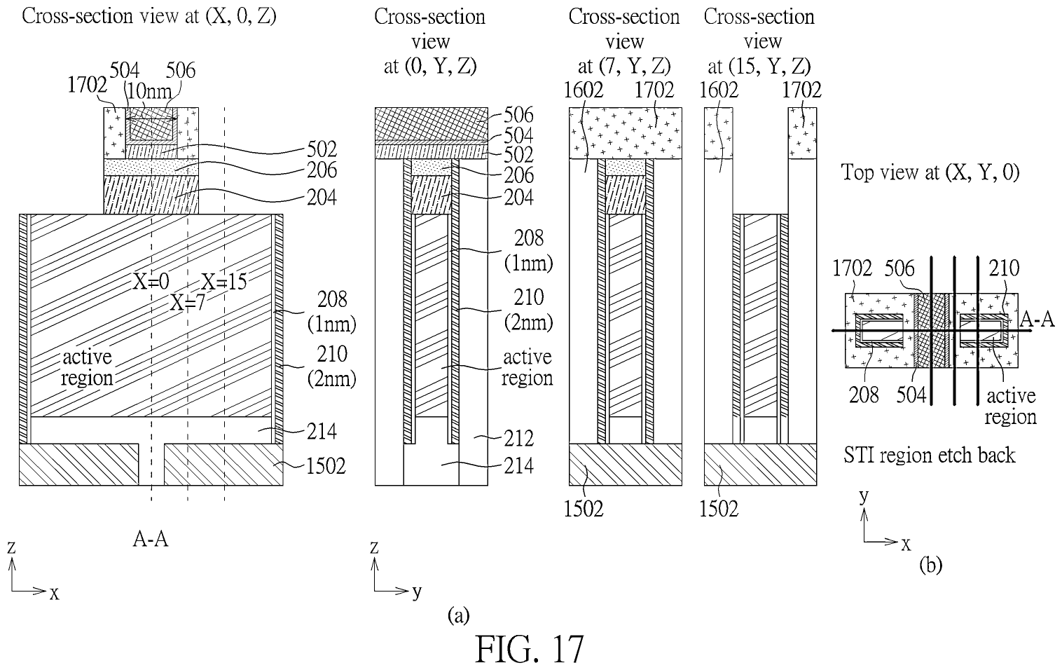

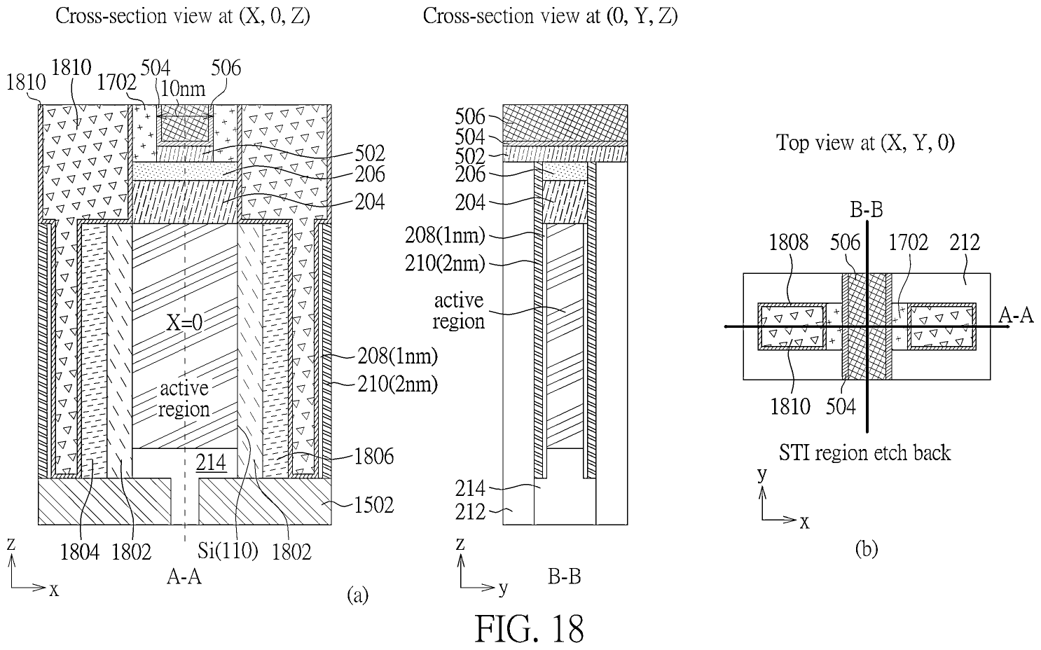

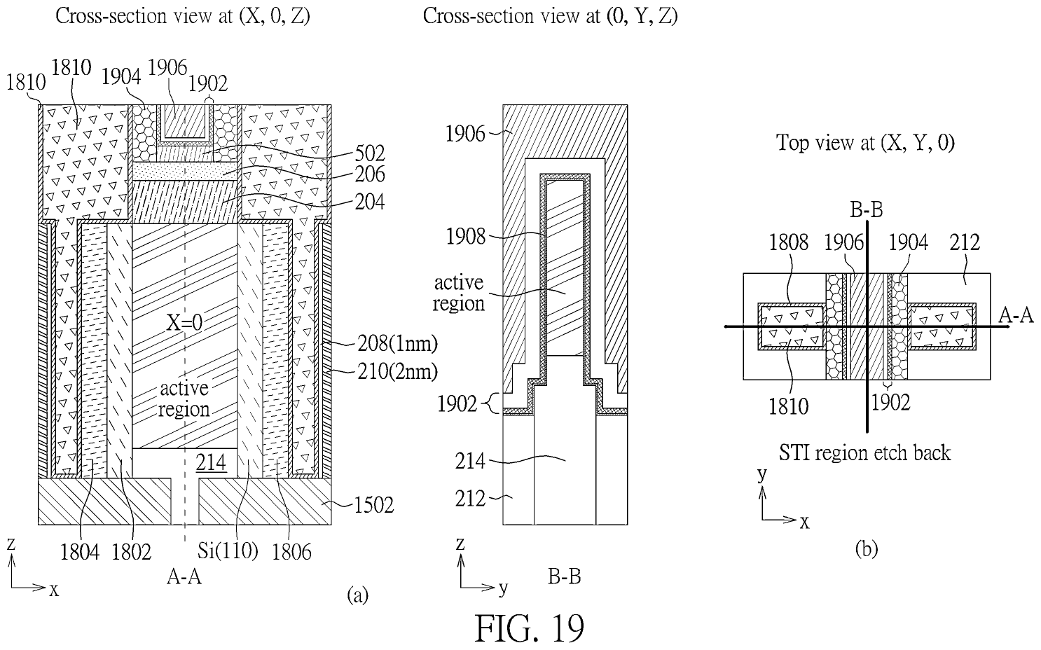

Then, please refer to FIG. 2E, FIG. 19. Step 50 to form exemplary gate region of the NMOS transistor could include:
Step 134: Use the well-known gate-last process to form the true gate region of the NMOS transistor (FIG. 19).

The following describes the processes to manufacture the OP-CMOSFET. In Step 102, as shown in FIG. 3(a), form the pad oxide layer 204 and the pad nitride layer 206 over the bulk semiconductor substrate.

In Step 104, as shown in FIG. 3(a), use the photolithographic masking technique to define the active region of the NMOS transistor in the bulk semiconductor substrate by the anisotropic etching technique to create the trench regions (e.g. about 300 nm deep) for future STI (Shallow Trench Isolation) region such that a convex structure of the active region (AA) is created.

Next, in Step 106, as shown in FIG. 3(a), form the oxide spacer (˜1 nm) 208 and then deposit the nitride spacer (˜2 nm) 210 as a solid wall to clamp the active region (or the narrow convex structure), especially the sidewalls of the convex structure. In another embodiment of the present invention, the solid clamping wall in the present invention could be a single layer or other composite layers to protect the narrow convex structure from collapse during the subsequent processes of forming the source region/drain region and the gate region of the NMOS transistor. Then use CMP (Chemical and Mechanical Polishing) technique to remove the excess oxide spacer 208 and the nitride spacer 210 to make a top surface of the pad nitride layer 206 in level up to an original semiconductor surface (OSS) of the bulk semiconductor substrate.

Then, in Step 108, as shown in FIG. 3(a), form the STI layer 212 (or thick oxide layer) into the trench region and use CMP technique to remove the excess oxide to achieve a planar surface in level up to the top surface of the pad-nitride layer 206. Again, the STI layer 212 (or thick oxide layer) further encompass or clamp the active region or the convex structure, especially the sidewalls of the convex structure, to protect the convex structure from collapse during the subsequent processes of forming the source region/drain region and the gate region of the NMOS transistor. In addition, as shown in FIG. 3(a), the active region is above an anti-punch-through layer 214, and the anti-punch-through layer 214 prevents punch through from occurring between the drain region and the bulk of the NMOS transistor. In addition, FIG. 3(b) is a top view corresponding to FIG. 3(a), wherein FIG. 3(a) includes two cross-sectional views (“A-A” and “B-B”) that are taken where indicated in FIG. 3(b), the cross-sectional view “A-A” corresponds to coordinates (x, 0, z), and the cross-sectional view “B-B” corresponds to coordinates (0, y, z).

Next, in Step 110, as shown in FIG. 4(a), afterward, the thin-amorphous SiC layer 402 is formed over the pad nitride layer 206 and the STI layer 212.

Then, in Step 112, as shown in FIG. 4(a), use the photolithographic mask to define the future gate-related area across the active region and the isolation region (the STI layer 212), and remove the SiC layer 402 in the gate-related area to reveal the pad-nitride layer 206. Then etch back portion of the revealed pad-nitride layer 206 around 5-10 nm. Thus, a smooth line edge roughness for the Damascene gate region is provided for following dummy gate. In addition, FIG. 4(b) is a top view corresponding to FIG. 4(a), wherein FIG. 4(a) includes two cross-sectional views (“A-A” and “B-B”) that are taken where indicated in FIG. 4(b).

Thereafter, in Step 114, as shown in FIG. 5(a), the dummy gate is formed by deposit the polysilicon spacer 502, the TiN layer 504, and the tungsten (W) layer 506 based on Damascene processes, wherein the width of the polysilicon spacer 502 is around 4 nm, the width of the dummy conductive gate (including the TiN layer 504 and the tungsten (W) layer 506) is around 10 nm.

Then, in Step 116, as shown in FIG. 5(a), the remained amorphous SiC layer 402 is then removed to expose the STI region 212. The exposed STI region 212 marked (dotted line circles) in FIG. 5(b) can be etched down to regenerate the convex structure outside the Damascene gate region.

Next, in Step 118, as shown in FIG. 5(a), the SiCOH spacer 508 is formed along the sidewalls of the convex structure outside the Damascene gate region. In addition, FIG. 5(b) is a top view corresponding to FIG. 5(a), wherein FIG. 5(a) includes two cross-sectional views (“A-A” and “B-B”) that are taken where indicated in FIG. 5(b).

Then, in Step 120, as shown in FIG. 6(a), anisotropic etch the polysilicon spacer 502. Then the exposed STI regions within the Damascene spacer regions are etched down (marked dotted line circles in FIG. 6(b)) to form the two concaves 602. In addition, FIG. 6(b) is a top view corresponding to FIG. 6(a), wherein FIG. 6(a) includes four cross-sectional views (“A-A”, “B-B”, “C-C”, “D-D”) that are taken where indicated in FIG. 6(b), the cross-sectional view “B-B” corresponds to coordinates (0, y, z), the cross-sectional view “C-C” corresponds to coordinates (7, y, z), and the cross-sectional view “D-D” corresponds to coordinates (15, y, z).

Then, in Step 122, as shown in FIG. 7(a), the SiCOH spacer 702 is then formed in the two concaves 602 (the Damascene spacer regions) as the Damascene SiCOH spacer. Thereafter, the STI regions 212 not covered by the dummy gate are etched and the previous clamping spacer (the nitride spacer 210 (Si₃N₄)/the oxide spacer 208=2/1 nm) is removed to reveal the semiconductor sidewalls. It is noted that the semiconductor sidewalls under the dummy gate are not revealed. In addition, FIG. 7(b) is a top view corresponding to FIG. 7(a), wherein FIG. 7(a) includes four cross-sectional views corresponds to coordinates (x, 0, z), (0, y, z), (7, y, z), and (15, y, z), respectively.

On the other hand, for PMOS transistor of OP-CMOSFET in one embodiment, there is no Damascene gate region. Therefore, the processes shown in FIG. 4 to FIG. 7 can be skipped. Thus, after the process in FIG. 3 for PMOS transistor, as shown in FIG. 8(a), the STI layer 212 is etched down, and a SiCOH spacer 802 is then formed to cover the sidewalls of the convex structure. Thereafter, as shown in FIG. 8(a), the STI layer 212 is etched down again and the previous clamping spacer (the nitride spacer 210 (Si₃N₄)/the oxide spacer 208=2/1 nm) is removed to reveal the semiconductor sidewalls. Unlike the previously mentioned active region of the NMOS transistor of the OP-CMOSFET, all semiconductor sidewalls of the convex structure under the SiCOH spacer 802 are revealed. In addition, FIG. 8(b) is a top view corresponding to FIG. 8(a), wherein FIG. 8(a) includes two cross-sectional views (“A-A” and “B-B”) that are taken where indicated in FIG. 8(b).

In addition, FIG. 9(a) shows 3D structure of the active region for the PMOS transistor without the Damascene gate region, and FIG. 9(b) shows 3D structure of the active region for the NMOS transistor with the Damascene gate region. Again, for the NMOS transistor, semiconductor sidewalls under the dummy gate region are covered by the STI layer 212 and are not revealed, however, for the NMOS transistor, all semiconductor sidewalls of the convex structure under the SiCOH spacer 802 are revealed.

Based on the revealed semiconductor sidewalls, underground insulating layers (localized isolating layers) could be formed. As shown in FIG. 10 which is the Technology Computer-Aided Design (TCAD) simulation result, repeated oxidation against the revealed semiconductor sidewalls and removal oxide process are performed for the active region of the PMOS transistor. When the width of the active region is 10 nm, after three cycles of thermal oxidation at 700 degrees, the underground insulating layer 1002 is formed under the active region of the PMOS transistor, and the silicon body between the SiCOH spacer 802 is fully insulated from the semiconductor substrate. Then a Chemical vapor deposition (CVD) oxide 1004 can be deposited under the SiCOH spacer 802.

On the other hand, In Step 124, for the active region of the NMOS transistor, after three cycles of thermal oxidation based on the TCAD simulation, although an underground insulating layer is also formed under the active region of the NMOS transistor, the silicon body between the SiCOH spacer 502 is not fully insulated from the semiconductor substrate by the underground insulating layer, as shown in FIG. 11, wherein there is a star shape Si via 1102 existed between the silicon body and the semiconductor substrate.

In another embodiment of the present invention, the underground insulating layer could be formed by one step thermal oxidation at higher temperature, such 950 degrees or higher temperature (1000 degrees˜1250 degrees). FIG. 12 shows an underground insulating layer 1202 is formed under the active region of the PMOS based on one step thermal oxidation at 950 degrees (the TCAD simulation), and again the silicon body between the SiCOH spacer 802 is fully insulated from the semiconductor substrate. However, in FIG. 13 for the active region of the NMOS transistor, after one step thermal oxidation at 1000 degrees is performed (the TCAD simulation), an underground insulating layer is formed, but the silicon body between the SiCOH spacer 502 is not fully insulated from the semiconductor substrate by the underground insulating layer due to the existence of the wider Si via 1302 which is a non-regular shape.

FIG. 14(a) shows, after the underground insulating layer (“UGOX”) is formed, the 3D structure of the active region for the PMOS transistor without Damascene gate region, and FIG. 14(b) shows the 3D structure of the active region for the NMOS with Damascene gate region. Although not shown in FIG. 14(b), there is Si via (e.g. the Si via 1102 shown in FIG. 11) between the silicon body of the NMOS transistor and the semiconductor substrate.

Thereafter, the true gate structure and the source/drain regions could be formed for the PMOS and NMOS transistors. Using the NMOS transistor as example, FIG. 15(a) shows cross section views at coordinates (x, 0, z), (0, y, z), (7, y, z), (15, y, z) of active region of the NMOS transistor after an underground insulating layer 1502 is finished. In addition, FIG. 15(b) is a top view corresponding to FIG. 15(a).

Then, in Step 126, as shown in FIG. 16(a), the SiCOH spacers 508, 702 are removed, and the STI layer 1602 is deposited and then etched back. In addition, FIG. 16(b) is a top view corresponding to FIG. 16(a), wherein FIG. 16(a) includes four cross-sectional views at coordinates (x, 0, z), (0, y, z), (7, y, z), (15, y, z).

Then, in Step 128, as shown in FIG. 17(a), the a-SiC layer 1702 as the virtual mask is deposited. Then, the exposed pad nitride layer 206 (and the pad oxide layer 204 is under the exposed pad nitride layer 206) corresponding to the source/drain region is removed to reveal the silicon body. In addition, FIG. 17(b) is a top view corresponding to FIG. 17(a), wherein FIG. 17(a) includes four cross-sectional views at coordinates (x, 0, z), (0, y, z), (7, y, z), (15, y, z).

Next, in Step 130, as shown in FIG. 18(a), first the exposed Si surface is etched to form the trenches and reveal two vertical Si edges with crystalline orientation (110). Then, use selective growth technique (such as selective epitaxy growth) to form the n-type LDD region 1802 and then the n+ doped source region 1804 and the n+ drain region 1806 based on those vertical Si edges with crystalline orientation (110). To be mentioned, no ion-implantations for forming all channel, drain and source regions are needed and no high temperature thermal annealing is required to remove those damages due to heavy bombardments of forming these regions.

Finally, in Step 132, as shown in FIG. 18(a), deposit the TiN layer 1808 and the Tungsten layer 1810 (could be carried out by Atomic Layer Deposition) and etching back (see A-A cross-section view and B-B cross-section view). In another embodiment, the top of the STI region 212 is higher than the original semiconductor surface of the substrate (i.e., is aligned with the top of the dummy gate), and moreover, two sides (top side and one sidewall) of the n+ drain region 1806 (or the n+ doped source region 1804) are contacted by the TiN layer 1808/the Tungsten layer 1810 (and landing pad over the n+ drain region 1806 and the n+ doped source region 1804, if any), and therefore, the contact resistance is reduced accordingly. In addition, FIG. 18(b) is a top view corresponding to FIG. 18(a), wherein FIG. 18(a) includes two cross-sectional views (“A-A” and “B-B”) that are taken where indicated in FIG. 18(b).

Thereafter, in Step 134, as shown in FIG. 19(a), use the well-known gate-last process to form the true gate region of the NMOS transistor with suitable work function metal (WFM) 1902 and the low-k main spacer 1904. In addition, as shown in FIG. 19(a), then deposit Tungsten layer 1906, wherein High-K dielectric layer 1908 is formed between the active region and the work function metal (WFM) 1902. In addition, FIG. 19(b) is a top view corresponding to FIG. 19(a), wherein FIG. 19(a) includes two cross-sectional views (“A-A” and “B-B”) that are taken where indicated in FIG. 19(b).

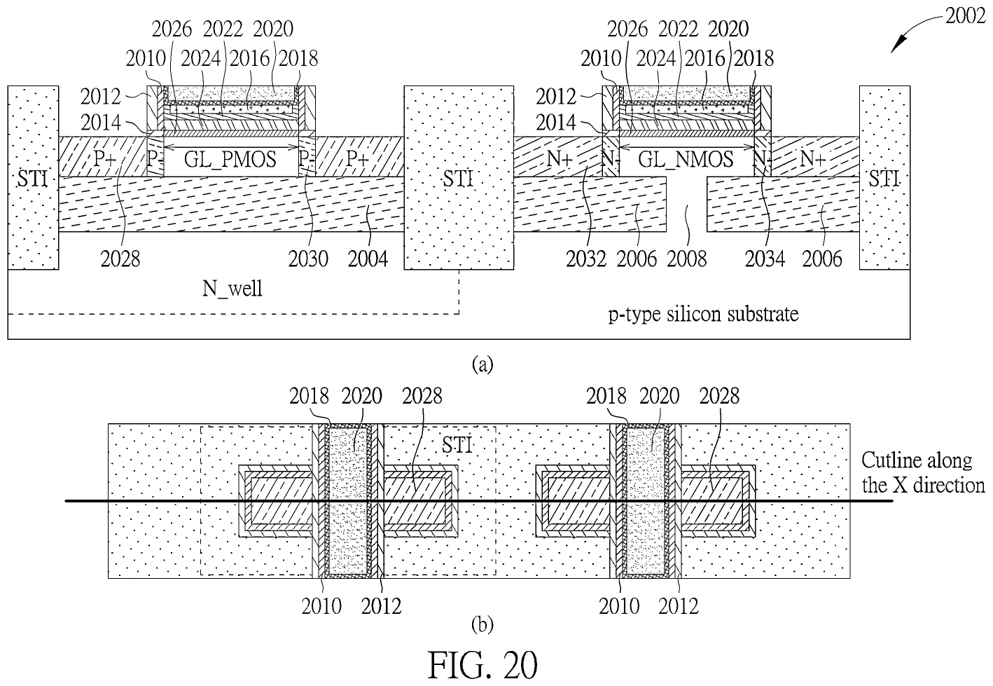

Therefore, a novel Oxide-PMOS Complementary Metal-Oxide-Semiconductor Field-Effect Transistor (OP-CMOSFET) 2002 based on a bulk semiconductor substrate, rather than a SOI structure, is shown in FIG. 20. The OP-CMOSFET 2002 has underground insulating layers 2004, 2006 formed under the PMOS transistor and NMOS transistor respectively, thus the leakage current and latch up issues could be improved. Moreover, the underground insulating layer 2004 under the PMOS transistor fully isolates the PMOS body from the bulk semiconductor substrate (i.e. N well). However, the underground insulating layer 2006 under the NMOS transistor only partially isolates the NMOS body from the bulk semiconductor substrate (i.e. p-type silicon substrate). The underground insulating layer 2006 under the NMOS body has a silicon opening/via (<4 nm, e.g. 2 nm or between 2˜4 nm) 2008 left, such that the NMOS body is still electrically coupled to the rest bulk semiconductor substrate. Thus, the floating body effect in the NMOS transistor could be improved. In addition, FIG. 20(b) is a top view corresponding to FIG. 20(a), wherein FIG. 20(a) is a cross-section view along a cutline of an X direction shown in FIG. 20(b). Furthermore, a length of the channel (GL PMOS) of the PMOS transistor is the same or substantially the same as a length of the channel (GL NMOS) of the NMOS transistor.

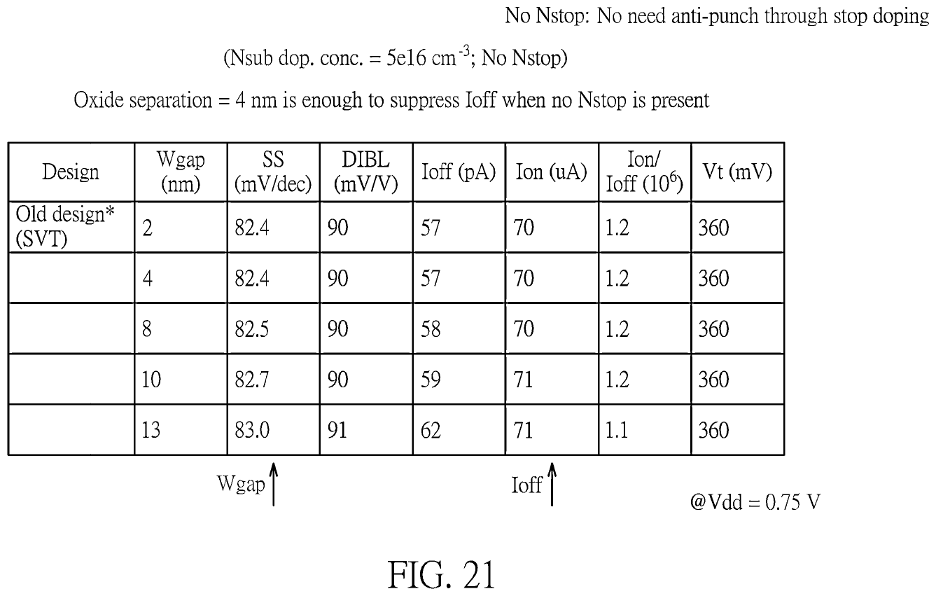

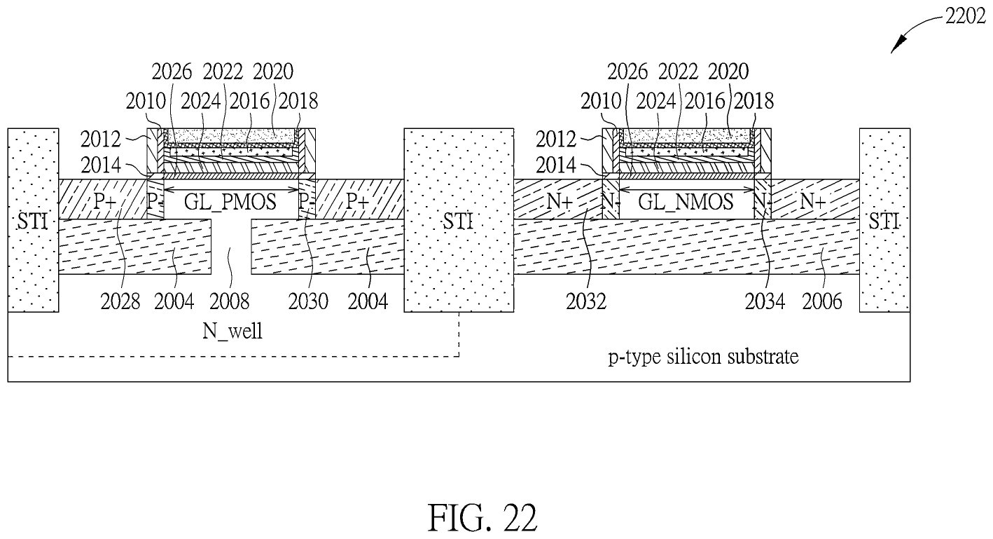

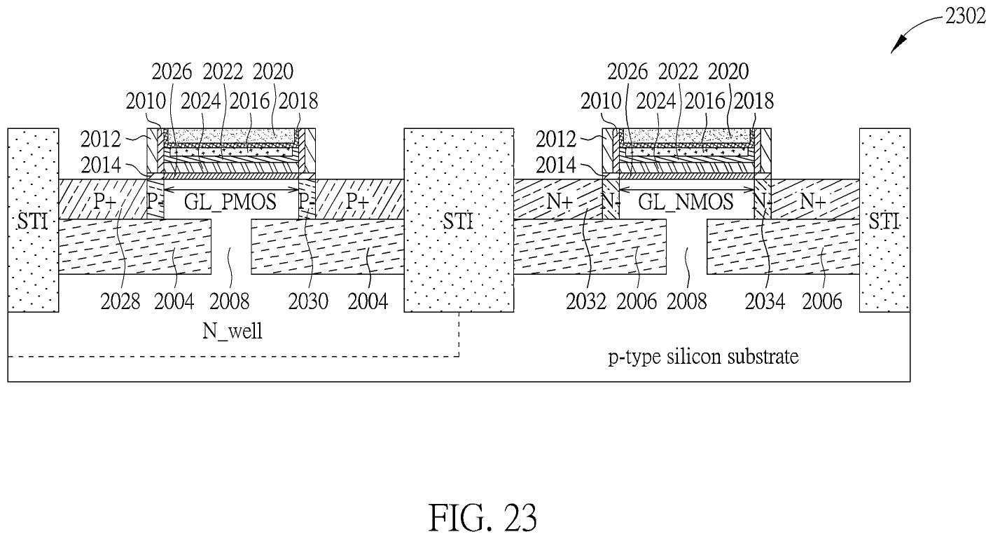

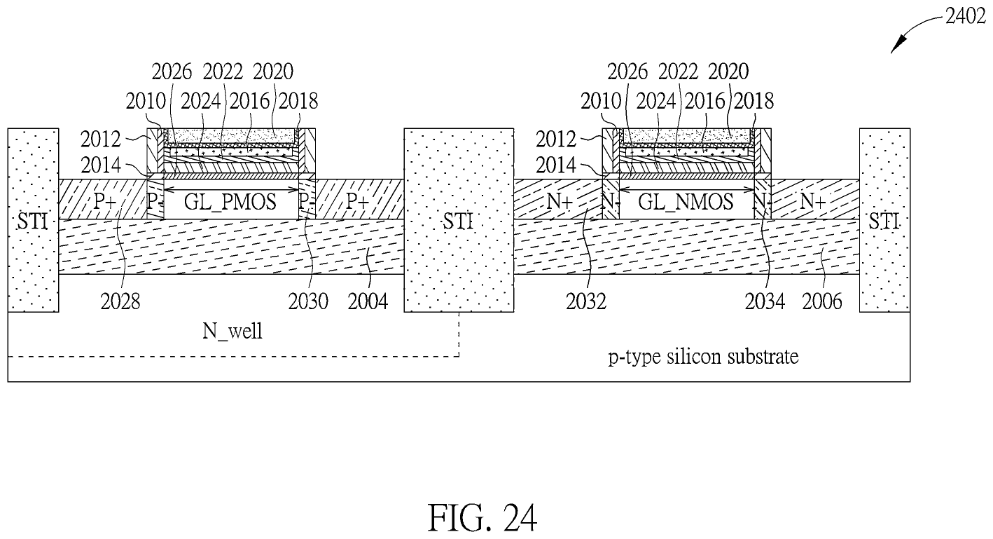

As shown in FIG. 21, even the underground insulating layer under the NMOS body has a silicon opening 2012 left, the TCAD simulation shows that the underground insulating layer 2006 in the NMOS structure applied with the above-mentioned Damascene dummy gate/spacer processes has <=4 nm silicon remained in the bottom and can have the same leakage (Ioff) as that with the underground insulating layer 2004 in the PMOS structure not applied with the above-mentioned Damascene dummy gate/spacer processes.

In addition, as shown in FIG. 22, the present invention could be applied to Oxide-NMOS Complementary Metal-Oxide-Semiconductor Field-Effect Transistor (ON-CMOSFET) 2202 based on a bulk semiconductor substrate, rather than a SOI structure. The ON-CMOSFET 2202 has underground insulating layers 2004, 2006 formed under the PMOS transistor and NMOS transistor respectively to improve the leakage current and latch up issues. Moreover, the underground insulating layer 2006 under the NMOS transistor fully isolates the NMOS body from the bulk semiconductor substrate. However, the underground insulating layer 2004 under the PMOS transistor only partially isolates the PMOS body from the bulk semiconductor substrate, such that the PMOS body is still electrically coupled to the rest bulk semiconductor substrate. Thus, the floating body effect in the PMOS transistor could be improved.

Of course, in another embodiment of the present invention, partial-Oxide Complementary Metal-Oxide-Semiconductor Field-Effect Transistor (PO-CMOSFET) 2302 is proposed as shown in FIG. 23. The PO-CMOSFET 2302 has underground insulating layers 2004, 2006 formed under the PMOS transistor and NMOS transistor respectively to improve the leakage current and latch up issues, wherein the underground insulating layer 2006 under the NMOS transistor only partially isolates the NMOS body from the bulk semiconductor substrate, and the underground insulating layer 2004 under the PMOS transistor only partially isolates the PMOS body from the bulk semiconductor substrate. Therefore, the PMOS body and the NMOS body are still electrically coupled to the rest bulk semiconductor substrate. Thus, the floating body effect in the PMOS transistor and NMOS transistor could be improved.

Furthermore, in another embodiment of the present invention, Oxide-PMOS-NMOS Complementary Metal-Oxide-Semiconductor Field-Effect Transistor (OPN-CMOSFET) 2402 is proposed as shown in FIG. 24. The OPN-CMOSFET 2402 has the underground insulating layers 2004, 2006 formed under the PMOS transistor and NMOS transistor respectively, thus the leakage current and latch up issues could be improved. Both the underground insulating layer 2006 under the NMOS transistor fully isolates the NMOS body from the bulk semiconductor substrate, and the underground insulating layer 2004 under the PMOS transistor fully isolates the PMOS body from the bulk semiconductor substrate as well. In addition, GL PMOS represents gate region of the PMOS transistor and GL NMOS represents gate region of the NMOS transistor.

In addition, as shown in FIG. 20, FIG. 22, FIG. 23, FIG. 24, there exists nitride spacer 2010, oxide spacer 2012, oxide layer 2014, Tungsten 2016, cap nitride layer 2018, cap oxide layer 2020, Ti/TiN metal layer 2022, N+ polysilicon 2024, gate oxide 2026, P+ region 2028, P-region 2030, N+ region 2032, and N-region 2034, wherein relative positions between the nitride spacer 2010, the oxide spacer 2012, the oxide layer 2014, the Tungsten 2016, the cap nitride layer 2018, the cap oxide layer 2020, the Ti/TiN metal layer 2022, the N+ polysilicon 2024, the gate oxide 2026, the P+ region 2028, the P-region 2030, the N+ region 2032, and the N-region 2034 can be referred to FIG. 20, so further description thereof is omitted for simplicity.

To sum up, the present invention has some advantages as follows:

1. The present invention can form underground insulating layers in the Bulk substrate without a need of buying an entire SOI Wafer which is very expensive.

2. With the underground insulating layers under the PMOS transistor and NMOS transistor, the leakage current and latch up issues in the CMOS structure could be improved.

3. The underground insulating layer under the PMOS transistor and/or NMOS transistor could partially isolate the PMOS transistor and/or NMOS transistor from the Bulk semiconductor substrate, such that the floating body effect in the conventional SOI Wafer could be solved.

4. By using selective growth of lightly/heavily doped layers to form the source region/drain region, there is no ion-implantation process for doping the source region/drain region.

5. Since the vertical length of the PMOS body/NMOS body is around 5˜10 nm, the reduction of the junction area of the source region/drain region will also lead to the reduction of a leakage current.

Although the present invention has been illustrated and described with reference to the embodiments, it is to be understood that the invention is not to be limited to the disclosed embodiments, but on the contrary, is intended to cover various modifications and equivalent arrangements included within the spirit and scope of the appended claims.

What is claimed is:

1. A CMOS (complementary metal-oxide-semiconductor) circuit, comprising:
a bulk semiconductor substrate with an original semiconductor surface;
a first active region and a second active region formed based on the bulk semiconductor substrate;
a first type transistor formed based on the first active region and having a first doped body;
a first localized isolating layer under the first type transistor and at least isolating the first doped body from the bulk semiconductor substrate;
a second type transistor formed based on the second active region and having a second doped body; and
a second localized isolating layer under the second type transistor and at least partially isolating the second doped body from the bulk semiconductor substrate.

2. The CMOS circuit in claim 1, further comprising:
a first shallow trench isolation region surrounding the first active region and the first localized isolating layer; and
a second shallow trench isolation region surrounding the second active region and the second localized isolating layer.

3. The CMOS circuit in claim 1, wherein the first localized isolating layer fully isolates the first type transistor from the bulk semiconductor substrate, and the second localized isolating layer only partially isolates the second type transistor from the bulk semiconductor substrate, wherein the first type transistor is a PMOS (p-type metal-oxide-semiconductor) transistor and the second type transistor is an NMOS (n-type metal-oxide-semiconductor) transistor.

4. The CMOS circuit in claim 3, wherein the second localized isolating layer has an opening from which the second doped body of the NMOS transistor is electrically coupled to the bulk semiconductor substrate.

5. The CMOS circuit in claim 4, wherein a length of the opening is around 2˜4 nm.

6. The CMOS circuit in claim 5, wherein the opening is a star shape or a non-regular shape.

7. The CMOS circuit in claim 1, wherein the first localized isolating layer only partially isolates the first type transistor from the bulk semiconductor substrate, and the second localized isolating layer fully isolates the second type transistor from the bulk semiconductor substrate, wherein the first type transistor is a PMOS transistor and the second type transistor is an NMOS transistor.

8. The CMOS circuit in claim 7, wherein the first localized isolating layer has an opening from which the first doped type body of the PMOS transistor body is electrically coupled to the bulk semiconductor substrate.

9. The CMOS circuit in claim 1, wherein the first localized isolating layer fully isolates the first type transistor from the bulk semiconductor substrate, and the second localized isolating layer fully isolates the second type transistor from the bulk semiconductor substrate, wherein the first type transistor is a PMOS transistor and the second type transistor is an NMOS transistor.

10. The CMOS circuit in claim 1, wherein a source region of the first type transistor abuts against the first localized isolating layer.

11. The CMOS circuit in claim 10, further comprising a metal region contacting a top surface and a sidewall of the source region.

12. The CMOS circuit in claim 1, wherein a channel length of the first type transistor is the same or substantially a channel length of the second type transistor.

13. A CMOS circuit, comprising:
a bulk semiconductor substrate with an original semiconductor surface;
a first active region and a second active region formed based on the bulk semiconductor substrate;
a PMOS transistor formed based on the first active region and having a first doped body and a first channel;
a first localized isolating layer under the PMOS transistor and at least isolating the first doped body from the bulk semiconductor substrate;
a first shallow trench isolation region surrounding the first active region and the first localized isolating layer;
an NMOS transistor formed based on the second active region and having a second doped body and a second channel;
a second localized isolating layer under the NMOS transistor and at least partially isolating the second doped body from the bulk semiconductor substrate; and
a second shallow trench isolation region surrounding the second active region and the second localized isolating layer;
wherein a length of the first channel is the same or substantially the same as a length of the second channel.

14. The CMOS circuit in claim 13, wherein the second localized isolating layer has an opening from which the second doped body of the NMOS transistor is electrically coupled to the bulk semiconductor substrate, and a shape of the opening is a star shape or irregular shape.

15. The CMOS circuit in claim 14, wherein a length of the opening is between 2˜4 nm.

16. The CMOS circuit in claim 14, wherein the opening is a star shape or a non-regular shape.

17. The CMOS circuit in claim 13, wherein a drain region of the first type transistor abuts against the first localized isolating layer.

18. The CMOS circuit in claim 17, further comprising a metal region contacting a top surface and a sidewall of the drain region.
